(19) United States
(12) Patent Application Publication
(10) Pub. No.: US 2025/0301659 A1
(43) Pub. Date: Sep. 25, 2025

(54) Scaled Two-Transistor-One-Capacitor Semiconductor Device

(71) Applicant: INTERNATIONAL BUSINESS MACHINES CORPORATION, ARMONK, NY (US)

(72) Inventors: Debarghya Sarkar, Latham, NY (US); Ruilong Xie, Niskayuna, NY (US); Kevin Wayne Brew, Niskayuna, NY (US); Abir Shadman, Albany, NY (US)

(21) Appl. No.: 18/609,161

(22) Filed: Mar. 19, 2024

(51) Int. Cl. H10B 53/30

(52) U.S. Cl. CPC H10B 53/30

(57) ABSTRACT

A semiconductor device includes a first field effect transistor, a second field effect transistor stacked on top of the first field effect transistor, and a capacitor stacked on top of the second field effect transistor. A gate of the first field effect transistor is electrically connected to a source of the second field effect transistor and to a terminal of the capacitor. The first field effect transistor is supplied with power through a backside power delivery network.

### BACKGROUND

The present disclosure relates to the semiconductor device fields. In particular, the present disclosure relates to semiconductor devices having two transistors and one capacitor.

Two-transistor-one-capacitor (2T1C) refers to architecture of a semiconductor device having a first transistor, a second transistor, and a single capacitor. 2T1C devices are important circuit components for analog in-memory computing for artificial intelligence (AI) hardware and other applications.

### SUMMARY

Embodiments of the present disclosure include a semiconductor device. The semiconductor device includes a first field effect transistor, a second field effect transistor stacked on top of the first field effect transistor, and a capacitor stacked on top of the second field effect transistor. A gate of the first field effect transistor is electrically connected to a source of the second field effect transistor and to a terminal of the capacitor. The first field effect transistor is supplied with power through a backside power delivery network.

Additional embodiments of the present disclosure include a method of forming a semiconductor device. The method includes forming a first field effect transistor, forming a second field effect transistor on top of the first field effect transistor, and electrically connecting a source of the second field effect transistor with a gate of the first field effect transistor. The method further includes forming a capacitor in series with the source of the second field effect transistor and electrically connecting the first field effect transistor to a backside power delivery network to supply power to the first field effect transistor.

Additional embodiments of the present disclosure include a semiconductor device. The semiconductor device includes a first field effect transistor, a second field effect transistor stacked on top of the first field effect transistor, a capacitor stacked on top of the second field effect transistor, and a lateral interconnect. The lateral interconnect is electrically connected to a gate contact that is electrically connected to a gate of the first field effect transistor. The lateral interconnect is electrically connected to a source contact that is electrically connected to a source of the second field effect transistor. The source contact is electrically connected to a terminal of the capacitor.

The above summary is not intended to describe each illustrated embodiment or every implementation of the present disclosure.

### BRIEF DESCRIPTION OF THE DRAWINGS

The drawings included in the present disclosure are incorporated into, and form part of, the specification. They illustrate embodiments of the present disclosure and, along with the description, serve to explain the principles of the disclosure. The drawings are only illustrative of typical embodiments and do not limit the disclosure.

FIG. 1 illustrates a stacked semiconductor device having two transistors and one capacitor and having a backside power delivery network, in accordance with embodiments of the present disclosure.

FIG. 2 illustrates a flowchart of an example method for forming a stacked semiconductor device, in accordance with embodiments of the present disclosure.

FIG. 3A illustrates a cross-sectional schematic view of an example of a structure for use in the performance of the example method of FIG. 1, in accordance with embodiments of the present disclosure.

FIG. 3B illustrates a cross-sectional schematic view of an example of a structure following the performance of a portion of the example method of FIG. 2, in accordance with embodiments of the present disclosure.

FIG. 3C illustrates a cross-sectional schematic view of an example of a structure following the performance of a portion of the example method of FIG. 2, in accordance with embodiments of the present disclosure.

FIG. 3D illustrates a cross-sectional schematic view of an example of a structure following the performance of a portion of the example method of FIG. 2, in accordance with embodiments of the present disclosure.

FIG. 3E illustrates a cross-sectional schematic view of an example of a structure following the performance of a portion of the example method of FIG. 2, in accordance with embodiments of the present disclosure.

FIG. 3F illustrates a cross-sectional schematic view of an example of a structure following the performance of a portion of the example method of FIG. 2, in accordance with embodiments of the present disclosure.

FIG. 3G illustrates a cross-sectional schematic view of an example of a structure following the performance of a portion of the example method of FIG. 2, in accordance with embodiments of the present disclosure.

### DETAILED DESCRIPTION

According to an aspect of the present disclosure, there is provided a semiconductor device. The semiconductor device includes a first field effect transistor, a second field effect transistor stacked on top of the first field effect transistor, and a capacitor stacked on top of the second field effect transistor. A gate of the first field effect transistor is electrically connected to a source of the second field effect transistor and to a terminal of the capacitor. The first field effect transistor is supplied with power through a backside power delivery network. By supplying the first field effect transistor with power through the backside power delivery network, the footprint of the circuitry component can be reduced without compromising the interconnects.

In embodiments, the gate of the first field effect transistor is electrically connected to the terminal of the capacitor by a source contact that extends through the source of the second field effect transistor. Such embodiments enable area scaling of a two-transistor-one-capacitor semiconductor device by making the electrical connection vertically through the source.

In embodiments, the gate of the first field effect transistor is electrically connected to a lateral interconnect by a gate contact, the source of the second field effect transistor is electrically connected to the lateral interconnect by a source contact, and the lateral interconnect covers an uppermost surface of the gate contact and covers a lowermost surface of the source contact. Such embodiments enable area scaling of a two-transistor-one-capacitor semiconductor device by maintaining a robust interconnect between the gate contact and the source contact while also reducing the footprint of the circuitry component.

In embodiments, the first field effect transistor is supplied with signal through a backside contact. Such embodiments enable signal to be delivered to the bottom transistor of the stacked transistors without requiring complex routing and increased footprint of the circuitry component.

In embodiments, the capacitor includes a dielectric, and the dielectric is a ferroelectric high-k material. Such embodiments enable area scaling of a two-transistor-one-capacitor semiconductor device because such materials possesses hysteresis in their electrical characteristics, which can enhance their performance for memory applications.

According to an aspect of the present disclosure, there is provided a method of forming a semiconductor device. The method includes forming a first field effect transistor, forming a second field effect transistor on top of the first field effect transistor, and electrically connecting a source of the second field effect transistor with a gate of the first field effect transistor. The method further includes forming a capacitor in series with the source of the second field effect transistor and electrically connecting the first field effect transistor to a backside power delivery network to supply power to the first field effect transistor. By supplying the first field effect transistor with power through the backside power delivery network, the footprint of the circuitry component can be reduced without compromising the interconnects.

In embodiments, the first field effect transistor is formed using a monolithic approach. Such embodiments enable forming the first field effect transistor of the semiconductor device in a known and robust manner.

In embodiments, the second field effect transistor is formed using a bonded approach. Such embodiments enable forming the second field effect transistor of the semiconductor device in a known and robust manner.

In embodiments, the method further includes electrically connecting the first field effect transistor to a backside contact to supply signal to the first field effect transistor. Such embodiments enable signal to be delivered to the bottom transistor of the stacked transistors without requiring complex routing and increased footprint of the circuitry component.

In embodiments, electrically connecting the source of the second field effect transistor with the gate of the first field effect transistor includes forming a gate contact in direct contact with the gate and forming a source contact in direct contact with the source. Such embodiments enable area scaling of a two-transistor-one-capacitor semiconductor device by establishing robust contacts for electrical connection.

In embodiments, forming the source contact includes forming the source contact extending through the source. Such embodiments enable area scaling of a two-transistor-one-capacitor semiconductor device by making the electrical connection vertically through the source.

In embodiments, electrically connecting the source of the second field effect transistor with the gate of the first field effect transistor includes forming a lateral interconnect that covers an uppermost surface of the gate contact and covers a lowermost surface of the source contact. Such embodiments enable area scaling of a two-transistor-one-capacitor semiconductor device by maintaining a robust interconnect between the gate contact and the source contact while also reducing the footprint of the circuitry component.

In embodiments, the lateral interconnect is formed after the first field effect transistor and before the second field effect transistor. Such embodiments enable forming the field effect transistors of the semiconductor device in a known and robust manner.

According to an aspect of the present disclosure, there is provided a semiconductor device. The semiconductor device includes first field effect transistor, a second field effect transistor stacked on top of the first field effect transistor, and a capacitor stacked on top of the second field effect transistor. The semiconductor device further includes a lateral interconnect that is electrically connected to a gate contact that is electrically connected to a gate of the first field effect transistor. The lateral interconnect is electrically connected to a source contact that is electrically connected to a source of the second field effect transistor. The source contact is electrically connected to a terminal of the capacitor. By utilizing such a lateral interconnect between the two stacked field effect transistors, such embodiments enable area scaling of a two-transistor-one-capacitor semiconductor device by maintaining a robust interconnect between the gate contact and the source contact while also reducing the footprint of the circuitry component.

In embodiments, the source contact extends through the source of the second field effect transistor. Such embodiments enable area scaling of a two-transistor-one-capacitor semiconductor device by making the electrical connection vertically through the source.

In embodiments, the lateral interconnect covers an uppermost surface of the gate contact and a lowermost surface of the source contact. Such embodiments enable area scaling of a two-transistor-one-capacitor semiconductor device by establishing a robust interconnect between the gate contact and the source contact vertically.

In embodiments, the lateral interconnect spans a horizontal distance between the uppermost surface of the gate contact and the lowermost surface of the source contact. Such embodiments enable area scaling of a two-transistor-one-capacitor semiconductor device by establishing a robust interconnect between the gate contact and the source contact horizontally.

In embodiments, the first field effect transistor is supplied with power through a backside power delivery network. By supplying the first field effect transistor with power through the backside power delivery network, the footprint of the circuitry component can be reduced without compromising the interconnects.

In embodiments, the first field effect transistor is supplied with signal through a backside contact. Such embodiments enable signal to be delivered to the bottom transistor of the stacked transistors without requiring complex routing and increased footprint of the circuitry component.

In embodiments, the capacitor includes a dielectric, and the dielectric is a ferroelectric high-k material. Such embodiments enable area scaling of a two-transistor-one-capacitor semiconductor device because such materials possesses hysteresis in their electrical characteristics, which can enhance their performance for memory applications.

Aspects of the present disclosure relate generally to the electrical, electronic, and computer fields. In particular, the present disclosure relates to two-transistor-one-capacitor (2T1C) semiconductor devices having stacked field effect transistors (FETs) and a backside power delivery network (BSPDN). While the present disclosure is not necessarily limited to such applications, various aspects of the disclosure may be appreciated through a discussion of various examples using this context.

Various embodiments of the present disclosure are described herein with reference to the related drawings. Alternative embodiments can be devised without departing from the scope of the present disclosure. It is noted that various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements. It should be noted, the term “selective to,” such as, for example, “a first element selective to a second element,” means that a first element can be etched, and the second element can act as an etch stop.

In general, the various processes used to form a micro-chip that will be packaged into an IC fall into four general categories, namely, film deposition, removal/etching, semiconductor doping and patterning/lithography.

Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Another deposition technology is plasma enhanced chemical vapor deposition (PECVD), which is a process which uses the energy within the plasma to induce reactions at the wafer surface that would otherwise require higher temperatures associated with conventional CVD. Energetic ion bombardment during PECVD deposition can also improve the film's electrical and mechanical properties.

Removal/etching is any process that removes material from the wafer. Examples include etch processes (either wet or dry), chemical-mechanical planarization (CMP), and the like. One example of a removal process is ion beam etching (IBE). In general, IBE (or milling) refers to a dry plasma etch method which utilizes a remote broad beam ion/plasma source to remove substrate material by physical inert gas and/or chemical reactive gas means. Like other dry plasma etch techniques, IBE has benefits such as etch rate, anisotropy, selectivity, uniformity, aspect ratio, and minimization of substrate damage. Another example of a dry removal process is reactive ion etching (RIE). In general, RIE uses chemically reactive plasma to remove material deposited on wafers. With RIE the plasma is generated under low pressure (vacuum) by an electromagnetic field. High-energy ions from the RIE plasma attack the wafer surface and react with it to remove material.

Semiconductor doping is the modification of electrical properties by doping, for example, transistor sources and drains, generally by diffusion and/or by ion implantation. These doping processes are followed by furnace annealing or by rapid thermal annealing (“RTA”). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device.

Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and gradually the conductors, insulators and selectively doped regions are built up to form the final device.

Turning now to an overview of technologies that are more specifically relevant to aspects of the present disclosure, in general, 2T1C is an important circuit component in in-memory compute for artificial intelligence (AI) hardware and other applications. With increasing adoption of AI hardware, reducing the footprint of 2T1C components is increasingly essential. Reducing surface area is a challenge when the two FETs of a 2T1C component are separated by being arranged on a single layer. Stacking FETs is one strategy that can be used to reduce the footprint of circuit components. However, in the case of 2T1C components, stacking the FETs also introduces challenges and issues.

One challenge that arises when stacking the FETs is that the gate terminal of a first FET has to be connected to a source terminal of a second FET while also supplying power and signal to the first FET. Interconnects between the elements will tend to foul unless complex routing is used. Such complex routing increases the footprint of the component, therefore failing to solve the issue of reducing surface area of the 2T1C in an optimal way.

Embodiments of the present disclosure may enable reliable methods and structures for reducing the surface area of 2T1C components while maintaining proper interconnects by utilizing a BSPDN with the stacked FETs. Notably, simply using stacked FETs is not sufficient to achieve the desired scaling as frontside interconnects cannot be effectively connected to a bottom FET while allowing for connecting the gate of the bottom FET to the source of the top FET. In other words, stacking the FETs of the 2T1C component is not sufficient on its own, due to challenges in making the sufficient and reliable connections for the stacked FETs of the 2T1C. Using a BSPDN with the stacked FETs, as disclosed herein, can overcome such challenges.

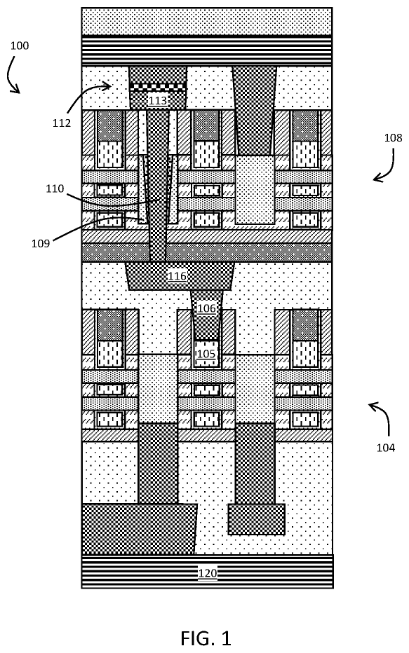

FIG. 1 depicts an example 2T1C device 100 including a BSPDN and stacked FETs. Accordingly, the device 100 shown in FIG. 1 includes a first FET 104, a second FET 108 stacked on top of the first FET 104, and a capacitor 112 stacked on top of the second FET 108. As shown, a gate 105 of the first FET 104 is electrically connected to a source 109 of the second FET 108 and to a terminal 113 of the capacitor 112. In particular, the gate 105 of the first FET 104 is electrically connected to the source 109 of the second FET 108 by a lateral interconnect 116 which extends from a gate contact 106 of the first FET 104 to a source contact 110 of the second FET 108. The source contact 110 extends vertically through the source 109 to the terminal 113 of the capacitor 112. Additionally, the device 100 includes a BSPDN 120, which delivers power to the first FET 104. In other words, the first FET 104 of the device 100 is supplied with power through the BSPDN 120. Accordingly, as described in further detail below, the specific configuration of the device 100 enables scaling the 2T1C component while maintaining the sufficiency and reliability of the electrical connections between the necessary elements of the device 100.

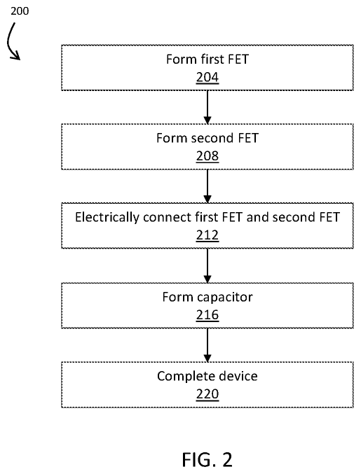

FIG. 2 depicts a flowchart of an example method 200 for forming a 2T1C device including a BSPDN and stacked FETs, according to embodiments of the present disclosure. The method 200 begins with operation 204, wherein a first FET is formed. The method 200 proceeds with operation 208, wherein a second FET is formed. The method 200 proceeds with operation 212, wherein the first FET and the second FET are electrically connected. The method 200 proceeds with operation 216, wherein a capacitor is formed. The method 200 concludes with operation 220, wherein the device is completed. More specifically, as described in further detail below, the method 200 includes forming a first FET (operation 204), forming a second FET on top of the first FET (operation 208), electrically connecting a source of the second FET with a gate of the first FET (operation 212), forming a capacitor in series with the source of the second FET (operation 216), and electrically connecting the first FET to a BSPDN to supply power to the first FET (operation 220). In embodiments of the present disclosure, the performance of each of the operations of method 200 may include the performance of one or more sub-operations.

In accordance with some embodiments of the present disclosure, the performance of operation 204, wherein the first FET is formed, can include using a monolithic approach to form a first level of the device. The performance of operation 204 can include formation of the first FET until the formation of the replacement metal gate structure. The formation of the first FET in the performance of operation 204 can include using known fabrication techniques not described in further detail herein.

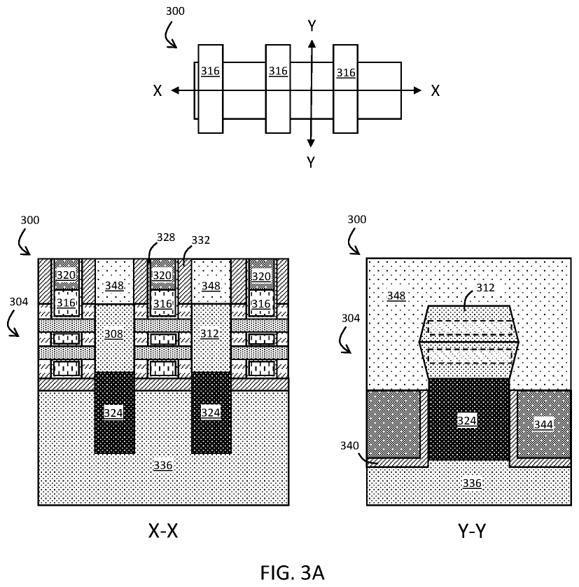

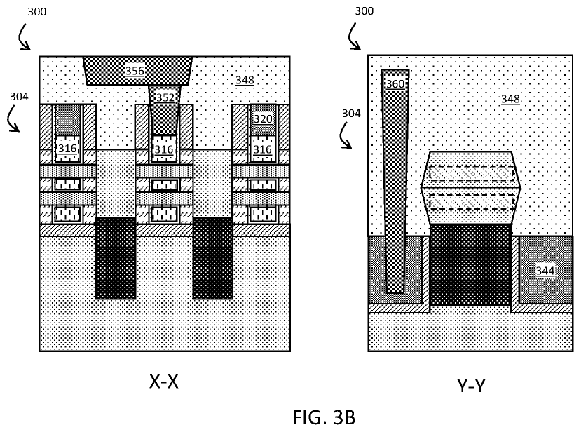

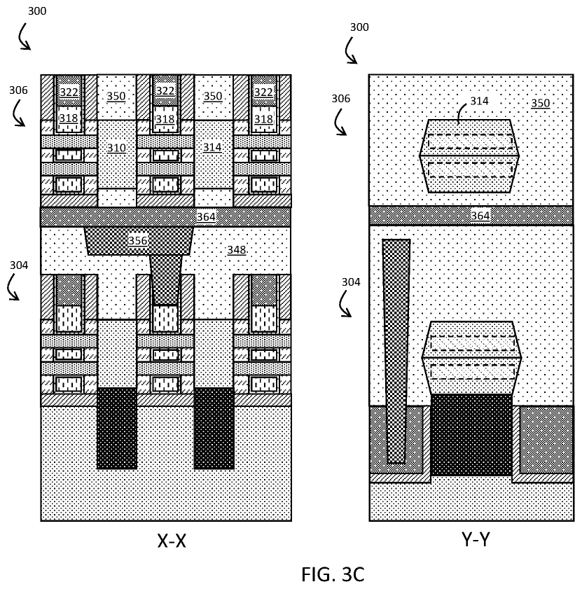

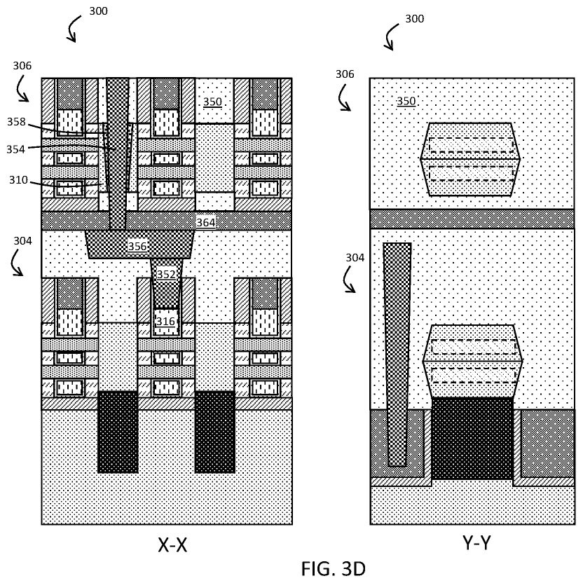

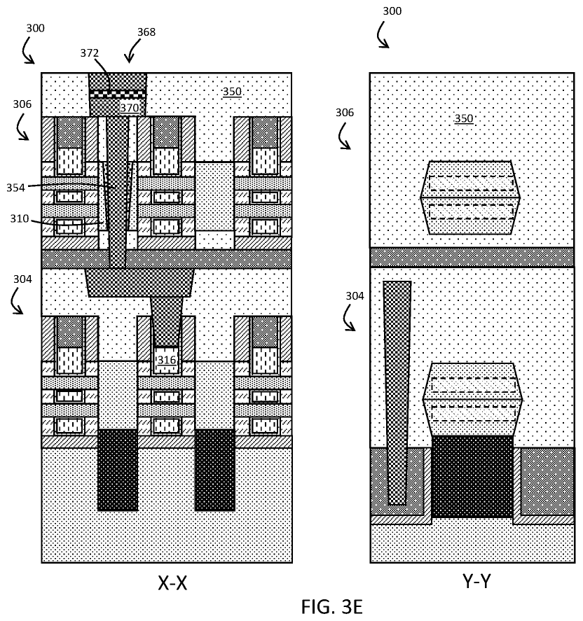

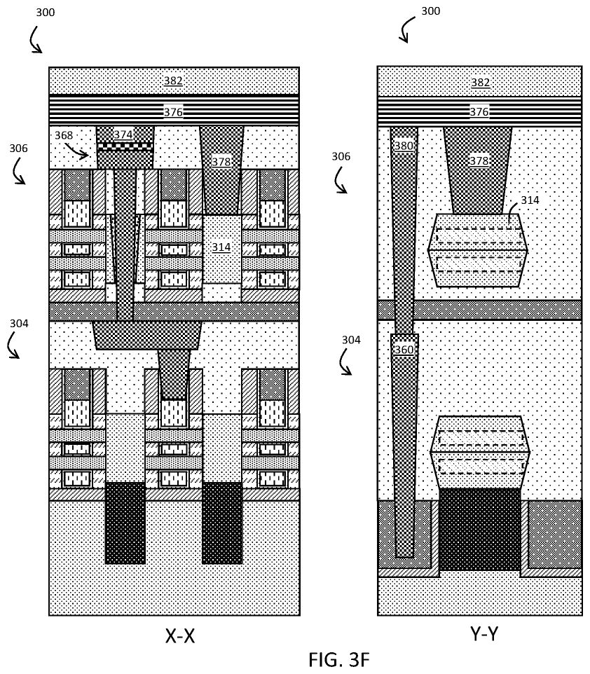

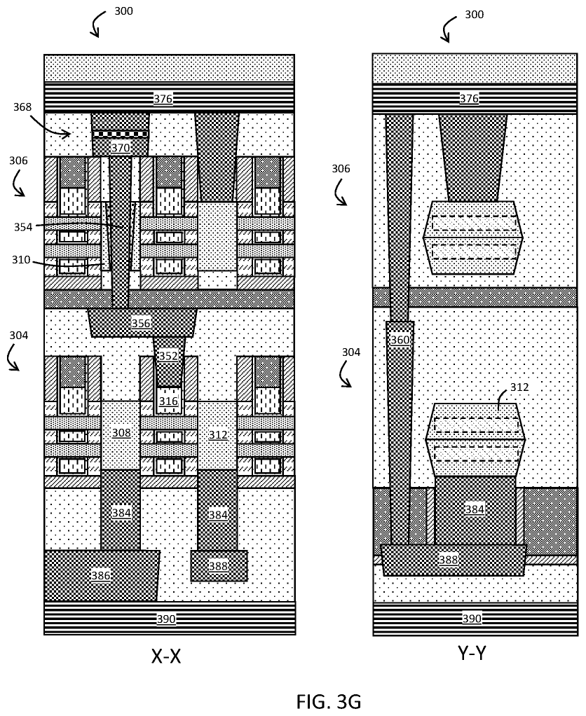

FIG. 3A illustrates a device 300 following the performance of this portion of operation 204. The X-X cross-section of the device 300 shown in FIG. 3A is cut along the X-X line illustrated in the top view schematic and is cut across gates of the first FET. Similarly, the Y-Y line shown in the top view schematic of the device 300 in FIG. 3A illustrates the cut which generates the Y-Y cross-section of the device 300, which is cut along an area of source/drain epitaxial material of the first FET, between gates. FIGS. 3B-3F use the same X-X and Y-Y cross-sections of the device 300 as those indicated in FIG. 3A.

As shown in FIG. 3A, the device 300 includes a first FET 304, which includes an area of source epitaxial material 308, an area of drain epitaxial material 312, and gates 316 formed between the areas of source and drain epitaxial material 308, 312. The first FET 304 also includes a sacrificial cap 320 in contact with the frontside of each of the gates 316 and placeholder material 324 in contact with the backside of each of the areas of source and drain epitaxial material 308, 312.

Notably, as used herein, the term “frontside” refers to the side of the device or component that is arranged toward the top of the page in the orientation depicted in the figures, and the term “backside” refers to the side of the device or component that is arranged toward the bottom of the page in the orientation depicted in the figures. These terms reflect conventional nomenclature regarding fabrication processes such that the “backside” is that which is arranged on the bottom or more downwardly during fabrication processes and the “frontside” is that which is arranged on the top or more upwardly during fabrication processes.

Accordingly, the sacrificial caps 320 in contact with the frontside of each of the gates 316 can also be describes as being in contact with an uppermost surface of each of the gates 316, and the placeholder material 324 in contact with the backside of each of the areas of source and drain epitaxial material 308, 312 can also be described as being in contact with a lowermost surface of each of the areas of source and drain epitaxial material 308, 312. The sacrificial caps 320 are lined with high-k metal gate material 328 and are arranged within dielectric spacers 332 of the first FET 304. In accordance with at least one embodiment, the dielectric spacers 332 can be, for example, SiBCN or a similar material having substantially similar material properties to enable substantially similar functionality in the particular application. The placeholder material 324 is arranged in a silicon substrate 336 of the first FET 304. In accordance with at least one embodiment, the placeholder material 324 can be, for example, SiGe or a similar material having substantially similar material properties to enable substantially similar functionality in the particular application.

As shown in the Y-Y cross-section of FIG. 3A, the placeholder material 324 is also lined with dielectric spacer material 340 and arranged within areas of shallow trench isolation (STI) 344, which can be referred to as a cell boundary region. In accordance with at least one embodiment, the areas of STI 344 can be, for example, an oxide material or a similar material having substantially similar material properties to enable substantially similar functionality in the particular application. As further illustrated in the X-X and Y-Y cross-sections of FIG. 3A, the area between the gates 316 of the first FET 304 can be filled with an oxide material 348 that is sufficient to electrically isolate the gates 316 from one another.

Returning to FIG. 2, in accordance with embodiments of the present disclosure, the performance of operation 204 of the method 200 can include forming electrical contacts for the first FET. More specifically, such embodiments can include forming a gate contact in direct contact with a gate of the first FET, forming a lateral interconnect in direct contact with the gate contact, and forming a via in the cell boundary region. As described in further detail below, the gate contact and the lateral interconnect will enable electrical connection of the first FET with the second FET and the capacitor, and the via will enable signal delivery to the first FET from the frontside of the device.

FIG. 3B illustrates the device 300 following the performance of this portion of operation 204. As shown, the device 300 includes a gate contact 352 in direct contact with a gate 316 of the first FET 304 and extending upwardly therefrom into oxide material 348 formed above the gates 316 of the first FET 304. More specifically, the gate contact 352 is formed in one of the sacrificial caps 320 such that it makes direct contact with an uppermost surface of the respective gate 316. The gate contact 352 is formed of a conductive material, such as metal, using known fabrication techniques. Accordingly, the formation of the gate contact 352 is not further described herein.

The device 300 further includes a lateral interconnect 356 in direct contact with the gate contact 352. More specifically, the lateral interconnect 356 is formed above the gate contact 352 and extends horizontally (in the orientation shown in the figures) relative to the gate contact 352. Accordingly, the lateral interconnect 356 is arranged within the oxide material 348 formed above the gates 316 of the first FET 304. The lateral interconnect 356 is formed of a conductive material, such as metal, using known fabrication techniques. Accordingly, the formation of the lateral interconnect 356 is not further described herein. Notably, the conductive material that forms the lateral interconnect 356 can be the same as the conductive material that forms the gate contact 352 or a different conductive material than that which forms the gate contact 352.

The device 300 further includes a via 360 formed in the cell boundary region between two gates 316. Accordingly, the via 360 is arranged in an area of STI 344 and extends upwardly therefrom into the oxide material 348 arranged above the area of STI 344. As described in further detail below, the via 360 will provide a way to deliver signal from the frontside of the device 300 to the first FET 304. The via 360 is formed of a conductive material, such as metal, using known techniques. Accordingly, the formation of the via 360 is not further described herein. Notably, the conductive material that forms the via 360 can be the same as the conductive material that forms the gate contact 352 or a different conductive material than that which forms the gate contact 352.

Returning to FIG. 2, following the performance of the above portions of operation 204, the first FET has been formed in accordance with embodiments of the method 200. Accordingly, the method 200 then proceeds to operation 208, wherein the second FET is formed. The formation of the known elements of the second FET in the performance of operation 208 can include using known fabrication techniques not described in further detail herein.

FIG. 3C illustrates the device 300 following the performance of this portion of operation 208. In accordance with at least one embodiment of the present disclosure, the second FET 306 includes substantially similar features as those described above with respect to the first FET 304. In particular, like the first FET 304, the second FET 306 includes an area of source epitaxial material 310, an area of drain epitaxial material 314, and gates 318 formed between the areas of source and drain epitaxial material 310, 314. The second FET 306 also includes a sacrificial cap 322 in contact with the frontside of each of the gates 318. The second FET 306 also includes an oxide material 350, which surrounds the areas of source and drain epitaxial material 310, 314 and is therefore arranged on the frontside and the backside of each of the areas of source and drain epitaxial material 310, 314.

In accordance with some embodiments of the present disclosure, the performance of operation 208, wherein the second FET is formed, can include using a bonding approach to form a second level of the device. In particular, the second FET can be bonded on top of the existing device, which includes the first FET and the lateral interconnect.

Accordingly, as shown in FIG. 3C, following the performance of this portion of operation 208, the device 300 includes a layer of bonding oxide 364, which bonds the second FET 306 on top of the first FET 304. In particular, the layer of bonding oxide 364 is in direct contact with the lateral interconnect 356 and the surrounding oxide material 348 of the first FET 304. The layer of bonding oxide 364 is also in direct contact with the oxide material 350 of the second FET 306.

Returning to FIG. 2, following the performance of the above portions of operation 208, the second FET has been formed in accordance with embodiments of the method 200. Accordingly, the method 200 then proceeds to operation 212, wherein the first FET and the second FET are electrically connected.

In accordance with some embodiments of the present disclosure, the performance of operation 212, wherein the first and second FETs are electrically connected, can include forming a source contact that is electrically connected to the lateral interconnect. In particular, forming the source contact can include forming a through-silicon contact that extends through the epitaxial material of the source of the second FET. In such embodiments, the through-silicon contact can be formed using known fabrication techniques not described in further detail herein. In such embodiments, the through-silicon via is isolated from the silicon of the source of the second FET by a silicide liner.

Thus, in accordance with embodiments of the present disclosure, electrically connecting the source of the second FET with the gate of the first FET can include forming a gate contact in direct contact with the gate and forming a source contact in direct contact with the source. In accordance with embodiments of the present disclosure, electrically connecting the source of the second FET with the gate of the first FET can further include forming the source contact extending through the source. In accordance with embodiments of the present disclosure, electrically connecting the source of the second FET with the gate of the first FET can include forming a lateral interconnect that covers an uppermost surface of the gate contact and covers a lowermost surface of the source contact. In accordance with embodiments of the present disclosure, the lateral interconnect can be formed after the first FET, or as part of forming the first FET, and before the second FET.

FIG. 3D illustrates the device 300 following the performance of this portion of operation 212, wherein the first and second FETs are electrically connected. Accordingly, FIG. 3D includes a source contact 354 formed vertically through the area of source epitaxial material 310 of the second FET 306. The source contact 354 is further formed so as to extend through the oxide material 350 arranged above and below the area of source epitaxial material 310 of the second FET 306 as well as through the layer of bonding oxide 364. Thus, the source contact 354 is formed so as to be in direct contact with the lateral interconnect 356 and to extend vertically through the bonding layer 364 and the entire thickness of the second FET 306.

Because the lateral interconnect 356 is electrically connected to the gate contact 352 of the first FET 304 and is electrically connected to the source contact 354 of the second FET 306, the lateral interconnect 356 enables electrical contact to be established between the gate 316 of the first FET 304 and the source 310 of the second FET 306 without the need for complex wire routing between the stacked FETs 304, 306. In particular, the gate 316 of the first FET 304 is electrically connected to the lateral interconnect 356 by the gate contact 352, the source 310 of the second FET 306 is electrically connected to the lateral interconnect 356 by the source contact 354, and the lateral interconnect 356 covers an uppermost surface of the gate contact 352 and covers a lowermost surface of the source contact 354.

Returning to FIG. 2, following the performance of the above portions of operation 212, the first FET and second FET have been electrically connected in accordance with embodiments of the method 200. Accordingly, the method 200 then proceeds to operation 216, wherein the capacitor is formed. The formation of the known elements of the capacitor in the performance of operation 216 can include using known fabrication techniques not described in further detail herein.

In accordance with embodiments of the present disclosure, the performance of operation 216 can include forming the capacitor such that a terminal of the capacitor is electrically connected to the source contact. More specifically, in accordance with embodiments of the present disclosure, forming the capacitor can include forming a terminal of the capacitor in direct contact with an uppermost surface of the source contact. Embodiments of the present disclosure can further include forming the capacitor within a layer of oxide material that is arranged on top of the second FET.

In accordance with some embodiments of the present disclosure, the performance of operation 216 can further include forming the capacitor such that the capacitor includes a dielectric and such that the dielectric is a ferroelectric high-k material.

FIG. 3E illustrates the device 300 following the performance of this portion of operation 216, wherein the capacitor is formed. Accordingly, FIG. 3E includes a capacitor 368 that is formed such that a terminal 370 of the capacitor 368 is in direct contact with an uppermost surface of the source contact 354. Accordingly, the gate 316 of the first FET 304 is electrically connected to the terminal 370 of the capacitor 368 by the source contact 354 that extends through the source 310 of the second FET 306.

The capacitor 368 further includes a dielectric 372. As discussed above, in accordance with some embodiments of the present disclosure, the dielectric can be a ferroelectric high-k material. Such embodiments enable area scaling of a two-transistor-one-capacitor semiconductor device because such materials possesses hysteresis in their electrical characteristics, which can enhance their performance for memory applications. As shown, the capacitor 368 is formed within a layer of oxide material 350 that is arranged above the second FET 306. As shown, the layer of oxide material 350 can be merged with the oxide material 350 of the second FET 306 such that there is no distinction between the two layers of oxide material 350.

Returning to FIG. 2, following the performance of the above portions of operation 216, the capacitor has been formed in accordance with embodiments of the method 200. Accordingly, the method 200 then proceeds to operation 220, wherein the device is completed.

In accordance with embodiments of the present disclosure, the completion of the device can include forming frontside contacts for the device. More specifically, completion of the device can include forming a frontside interconnect layer, which can be used to supply signal to the device. Completion of the device can further include forming frontside contacts to electrically connect the first FET, the second FET, and the capacitor to the frontside interconnect layer. The formation of the known elements of the frontside interconnect layer and frontside contacts in the performance of operation 220 can include using known fabrication techniques not described in further detail herein. Such embodiments can also include forming a carrier wafer on the device, above the frontside interconnect layer. The carrier wafer enables subsequent processing on the backside of the device.

FIG. 3F illustrates the device 300 following the performance of this portion of operation 220. Accordingly, as shown, the device 300 includes a frontside interconnect layer 376 formed in direct contact with a second terminal 374 of the capacitor 368. Accordingly, the frontside interconnect layer 376 is electrically connected to the capacitor 368. The device 300 further includes a first frontside contact 378 which is formed in direct contact with the frontside interconnect layer 376 and with the area of epitaxial material of the drain 314 of the second FET 306. Accordingly, the frontside interconnect layer 376 is electrically connected to the second FET 306. The device 300 further includes a second frontside contact 380 which is formed in direct contact with the frontside interconnect layer 376 and with the via 360 formed in the cell boundary region of the first FET 304. Accordingly, as described in further detail below, the frontside interconnect layer 376 will be electrically connected to the first FET 304. As shown, the device 300 further includes a carrier wafer 382 bonded to the device 300 on top of the frontside interconnect layer 376.

In accordance with embodiments of the present disclosure, the completion of the device can further include forming backside contacts for the device. More specifically, completion of the device can include removing the silicon substrate from the backside of the device, removing the placeholders from the backside of the device, filling the openings left by the removed placeholders with a conductive material, forming backside contacts in contact with the conductive material, forming an oxide material to surround the conductive material and backside contacts, and forming a backside interconnect layer in contact with the backside contacts.

FIG. 3G illustrates the device 300 following the performance of this portion of operation 220. Accordingly, as shown, the device 300 includes areas of conductive material 384 formed by filling the openings left by removal of the placeholders 324 (shown in FIG. 3A). As shown, one area of conductive material 384 is formed in direct contact with a lowermost surface of the area of epitaxial material of the source 308 of the first FET 304 and another area of conductive material 384 is formed in direct contact with a lowermost surface of the area of epitaxial material of the drain 312 of the first FET 304. These areas of conductive material 384 will enable electrical contact to be established with the backsides of the first FET 304.

As shown in FIG. 3G, the device 300 further includes a first backside contact 386 in direct contact with the area of conductive material 384 that is formed in direct contact with the area of epitaxial material of the source 308 of the first FET 304. As shown, the first backside contact 386 is also in direct contact with a backside interconnect layer 390. Accordingly, the source 308 of the first FET 304 is electrically connected to the respective area of conductive material 384, the respective area of conductive material 384 is electrically connected to the first backside contact 386, and the first backside contact 386 is electrically connected to the backside interconnect layer 390. In this way, the backside of the first FET 304 can be supplied with power through a backside power delivery network, which can include and/or be electrically connected to the backside interconnect layer 390. This avoids having to arrange the components of the device 300 to otherwise enable power delivery to the first FET 304 from the frontside of the device 300 or from between the stacked FETs 304, 306.

The device 300 further includes a second backside contact 388 in direct contact with the area of conductive material 384 that is formed in direct contact with the area of epitaxial material of the drain 312 of the first FET 304. As shown, the second backside contact 388 is also in direct contact with the via 360. Accordingly, the drain 312 of the first FET 304 is electrically connected to the respective area of conductive material 384, the respective area of conductive material 384 is electrically connected to the second backside contact 388, and the second backside contact 388 is electrically connected to the via 360. In this way, the first FET 304 can be supplied with signal through the frontside interconnect layer 376 of the device 300. In other words, the first FET 304 is electrically connected to the second backside contact 388 to supply signal to the first FET 304. Thus, the first FET 304 is supplied with signal through the backside contact 388. Using the via 360 to connect the drain 312 of the first FET 304 with the frontside interconnect layer 376 on the backside of the first FET 304 avoids having to arrange the components of the device 300 to otherwise enable signal delivery from between the stacked FETs 304, 306.

The device 300 shown in FIG. 3G includes a first FET 304, a second FET 306 stacked on top of the first FET 304, a capacitor 368 stacked on top of the second FET 306, and a lateral interconnect 356. The lateral interconnect 356 is electrically connected to a gate contact 352 that is electrically connected to a gate 316 of the first FET 304. The lateral interconnect 356 is electrically connected to a source contact 354 that is electrically connected to a source 310 of the second FET 306. The source contact 354 is electrically connected to a terminal 370 of the capacitor 368. As shown, the source contact 354 extends vertically through the source 310 of the second FET 306. As shown, the lateral interconnect 356 covers an uppermost surface of the gate contact 352 and a lowermost surface of the source contact 354. As shown, the lateral interconnect 356 spans a horizontal distance (when viewed in the orientation of FIG. 3G) between the uppermost surface of the gate contact 352 and the lowermost surface of the source contact 354. Accordingly, as enabled by the configuration of the device 300 disclosed herein, the first FET 304 is supplied with power through a BSPDN through a backside interconnect layer 390. Additionally, the first FET 304 is supplied with signal through the second backside contact 388.

Thus, as shown in FIG. 3G, the device 300 enables the particular arrangement of components necessary for a 2T1C circuit with a stacked FET arrangement by enabling power delivery to the first FET from the backside of the device 300, by enabling signal delivery to the first FET from the frontside of the device 300, and by routing the source contact through the source of the second FET to establish an electrical connection between the first FET and the capacitor without introducing potential failure points between the stacked FETs.

In addition to embodiments described above, other embodiments having fewer operational steps, more operational steps, or different operational steps are contemplated. Also, some embodiments may perform some or all of the above operational steps in a different order. Furthermore, multiple operations may occur at the same time or as an internal part of a larger process.

In the foregoing, reference is made to various embodiments. It should be understood, however, that this disclosure is not limited to the specifically described embodiments. Instead, any combination of the described features and elements, whether related to different embodiments or not, is contemplated to implement and practice this disclosure. Many modifications and variations may be apparent to those of ordinary skill in the art without departing from the scope and spirit of the described embodiments. Furthermore, although embodiments of this disclosure may achieve advantages over other possible solutions or over the prior art, whether or not a particular advantage is achieved by a given embodiment is not limiting of this disclosure. Thus, the described aspects, features, embodiments, and advantages are merely illustrative and are not considered elements or limitations of the appended claims except where explicitly recited in a claim(s).

The terminology used herein is for the purpose of describing particular embodiments only and is not intended to be limiting of the various embodiments. As used herein, the singular forms “a,” “an,” and “the” are intended to include the plural forms as well, unless the context clearly indicates otherwise. It will be further understood that the terms “includes” and/or “including,” when used in this specification, specify the presence of the stated features, integers, steps, operations, elements, and/or components, but do not preclude the presence or addition of one or more other features, integers, steps, operations, elements, components, and/or groups thereof. In the previous detailed description of example embodiments of the various embodiments, reference was made to the accompanying drawings (where like numbers represent like elements), which form a part hereof, and in which is shown by way of illustration specific example embodiments in which the various embodiments may be practiced. These embodiments were described in sufficient detail to enable those skilled in the art to practice the embodiments, but other embodiments may be used, and logical, mechanical, electrical, and other changes may be made without departing from the scope of the various embodiments. In the previous description, numerous specific details were set forth to provide a thorough understanding the various embodiments. However, the various embodiments may be practiced without these specific details. In other instances, well-known circuits, structures, and techniques have not been shown in detail in order not to obscure embodiments.

As used herein, “a number of” when used with reference to items, means one or more items. For example, “a number of different types of networks” is one or more different types of networks.

When different reference numbers comprise a common number followed by differing letters (e.g., 100a, 100b, 100c) or punctuation followed by differing numbers (e.g., 100-1, 100-2, or 100.1, 100.2), use of the reference character only without the letter or following numbers (e.g., 100) may refer to the group of elements as a whole, any subset of the group, or an example specimen of the group.

Further, the phrase “at least one of,” when used with a list of items, means different combinations of one or more of the listed items can be used, and only one of each item in the list may be needed. In other words, “at least one of” means any combination of items and number of items may be used from the list, but not all of the items in the list are required. The item can be a particular object, a thing, or a category.

For example, without limitation, “at least one of item A, item B, or item C” may include item A, item A and item B, or item B. This example also may include item A, item B, and item C or item B and item C. Of course, any combinations of these items can be present. In some illustrative examples, “at least one of” can be, for example, without limitation, two of item A; one of item B; and ten of item C; four of item B and seven of item C; or other suitable combinations.

Different instances of the word “embodiment” as used within this specification do not necessarily refer to the same embodiment, but they may. Any data and data structures illustrated or described herein are examples only, and in other embodiments, different amounts of data, types of data, fields, numbers and types of fields, field names, numbers and types of rows, records, entries, or organizations of data may be used. In addition, any data may be combined with logic, so that a separate data structure may not be necessary. The previous detailed description is, therefore, not to be taken in a limiting sense.

The descriptions of the various embodiments of the present disclosure have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

Although the present invention has been described in terms of specific embodiments, it is anticipated that alterations and modification thereof will become apparent to the skilled in the art. Therefore, it is intended that the following claims be interpreted as covering all such alterations and modifications as fall within the true spirit and scope of the invention.

What is claimed is:

1. A semiconductor device, comprising:
a first field effect transistor;
a second field effect transistor stacked on top of the first field effect transistor; and
a capacitor stacked on top of the second field effect transistor, wherein:
a gate of the first field effect transistor is electrically connected to a source of the second field effect transistor and to a terminal of the capacitor, and
the first field effect transistor is supplied with power through a backside power delivery network.

2. The semiconductor device of claim 1, wherein:
the gate of the first field effect transistor is electrically connected to the terminal of the capacitor by a source contact that extends through the source of the second field effect transistor.

3. The semiconductor device of claim 1, wherein:
the gate of the first field effect transistor is electrically connected to a lateral interconnect by a gate contact;
the source of the second field effect transistor is electrically connected to the lateral interconnect by a source contact; and
the lateral interconnect covers an uppermost surface of the gate contact and covers a lowermost surface of the source contact.

4. The semiconductor device of claim 1, wherein:
the first field effect transistor is supplied with signal through a backside contact.

5. The semiconductor device of claim 1, wherein:
the capacitor includes a dielectric, and
the dielectric is a ferroelectric high-k material.

6. A method of forming a semiconductor device, the method comprising:
forming a first field effect transistor;
forming a second field effect transistor on top of the first field effect transistor;
electrically connecting a source of the second field effect transistor with a gate of the first field effect transistor;
forming a capacitor in series with the source of the second field effect transistor; and
electrically connecting the first field effect transistor to a backside power delivery network to supply power to the first field effect transistor.

7. The method of claim 6, wherein the first field effect transistor is formed using a monolithic approach.

8. The method of claim 6, wherein the second field effect transistor is formed using a bonded approach.

9. The method of claim 6, further comprising:
electrically connecting the first field effect transistor to a backside contact to supply signal to the first field effect transistor.

10. The method of claim 6, wherein:
electrically connecting the source of the second field effect transistor with the gate of the first field effect transistor includes forming a gate contact in direct contact with the gate and forming a source contact in direct contact with the source.

11. The method of claim 10, wherein:
forming the source contact includes forming the source contact extending through the source.

12. The method of claim 10, wherein:
electrically connecting the source of the second field effect transistor with the gate of the first field effect transistor includes forming a lateral interconnect that covers an uppermost surface of the gate contact and covers a lowermost surface of the source contact.

13. The method of claim 12, wherein:
the lateral interconnect is formed after the first field effect transistor and before the second field effect transistor.

14. A semiconductor device, comprising:
a first field effect transistor;
a second field effect transistor stacked on top of the first field effect transistor;
a capacitor stacked on top of the second field effect transistor; and
a lateral interconnect, the lateral interconnect electrically connected to a gate contact that is electrically connected to a gate of the first field effect transistor, the lateral interconnect electrically connected to a source contact that is electrically connected to a source of the second field effect transistor, wherein:
the source contact is electrically connected to a terminal of the capacitor.

15. The semiconductor device of claim 14, wherein:
the source contact extends through the source of the second field effect transistor.

16. The semiconductor device of claim 14, wherein:
the lateral interconnect covers an uppermost surface of the gate contact and a lowermost surface of the source contact.

17. The semiconductor device of claim 16, wherein:
the lateral interconnect spans a horizontal distance between the uppermost surface of the gate contact and the lowermost surface of the source contact.

18. The semiconductor device of claim 14, wherein:
the first field effect transistor is supplied with power through a backside power delivery network.

19. The semiconductor device of claim 14, wherein:
the first field effect transistor is supplied with signal through a backside contact.

20. The semiconductor device of claim 14, wherein:
the capacitor includes a dielectric, and
the dielectric is a ferroelectric high-k material.
